(19) United States
(12) Patent Application Publication
(10) Pub. No.: US 2002/0025378 A1
(43) Pub. Date: Feb. 28, 2002

(54) Tools with treated surfaces

(76) Inventors: Klaus Keller, Wangen (CH); Fritz Koch, Rheinfelden-Degerfelden (DE)

Correspondence Address: FOLEY, HOAG & ELIOT, LLP, PATENT GROUP, ONE POST OFFICE SQUARE, BOSTON, MA, 02109, US

(21) Appl. No.: 09/928,801

(22) Filed: Aug. 13, 2001

Related U.S. Application Data
(62) Division of application No. 09/419,200, filed on Oct. 15, 1999, now abandoned.

(30) Foreign Application Priority Data
Oct. 17, 1998 (DE) 198 48 025.3

(51) Int. Cl. C23C 16/00; C23C 14/00; C23C 16/34; B44C 1/22; H05K 3/07; C23C 14/34

(52) U.S. Cl. 427/255.31; 204/192.16; 204/192.3; 205/640; 205/660; 216/96; 216/100; 427/248.1; 427/255.38; 427/255.394; 427/290; 427/292; 427/307; 427/249.18; 427/534; 427/314; 427/318

(57) ABSTRACT

A method is disclosed for treating the surface of tools made of tool steel, wherein primary carbides are embedded in the tool steel matrix. The thickness of the primary carbides disposed near the surface can be reduced by forming a surface which has point-wise recess; alternatively, the primary carbides can be completely removed. A hard material layer is deposited on this surface. The invention also describes tools made of tool steel, wherein primary carbides are embedded in the tool steel matrix. The primary carbides are significantly recessed, and a hard material layer is deposited thereon.

### FIELD OF THE INVENTION

The present invention relates to a method for surface treatment of tools made of tool steel and having a matrix with embedded primary carbides, as well as tools having a steel matrix with embedded primary carbides and a treated surface.

### BACKGROUND OF THE INVENTION

Since quite some time, high-performance tools are provided with hard coatings to increase wear resistance. These coatings consist, for example, of nitrides, carbides, carbo nitrates and borides, which are formed at least of one metal taken from the group consisting of titanium, zirconium, chromium, tungsten, tantalum, vanadium, niobium and hafnium, with at least one light element, such as nitrogen, carbon and/or boron. The layers are deposited preferably with a CVD technique (CVD for chemical vapor deprivation) or PVD (PVD for physical vapor deprivation).

The tools are preferably made of ledeburitic cold work steel and high-performance high-speed steels (HSS). The hardness of these steels can be increased substantially by a suitable heat treatment. These steels can also incorporate very hard carbides which are embedded in the steel matrix. A distinction has to be made between primary (large) carbides and secondary (small) carbides. These carbides, in particular the primary carbides, such as carbides of the type M₇C₃, enhances the wear resistence of the tool steels, which makes the incorporation of a large carbide fraction by intended alloying of the steel highly desirable.

While the rounded secondary carbides which are only several micrometers in diameter, are relatively uniformly distributed in the steel matrix, meaning that they are not critical for the fracture mechanics, the more voluminous primary carbides which are two to three orders of magnitude larger, are relevant for the fracture mechanics. The effect is even more pronounced if the (mostly) coarse-grain primary carbides form distinct (carbide) rows and/or (carbide) clusters. Due to the different physical material characteristics (the steel matrix exhibits (micro) plastic characteristics/carbides which have a significantly higher elastic module, exhibit only linear-elastic characteristics, and not plastic characteristics), even a moderate external load tends to produce high strain peaks, which can produce cracks affecting the functionality.

The primary carbides, in particular carbides in surface regions exposed to high stress, are therefore critical starting points for (brittle) stress fractures in tools. The primary carbides have a built-in defect potential which is enhanced by cutting and machining of the surface as cutting of the brittle carbides in the shear plane of the cut leaves fragile rough carbide surfaces with isolated detached carbide particles. In regions with greater accumulation of carbides, brittle defect regions are formed which cannot support an external load, are formed, which produce initial microscopically small surface damage at highly stressed slide planes. The surface damage expands very rapidly particularly in the highly stressed regions, i.e., near protrusions, curved surfaces or cutting edges, followed by a sudden tool malfunction.

These microscopically small defect structures are present in all carbide-rich cast steels after metal cutting. Within certain limits, the defect structures can be smoothed by finish-machining, for example, by lapping or polishing, but are unlikely to be completely eliminated. Finish-machining may be sufficient for uncoated slide planes designed for a “normal” load, since the troubling defects can be reduced farther during a break-in period, wherein after the break-in a sufficient load-bearing capacity is acquired (training effect).

If on the other hand, the slide surfaces are coated, then such break-in periods are not feasible due to the applied, highly wear-resistant protection layer. Under these different conditions, the large (primary) carbides which are cut near the surface, may produce an additional potential malfunction when in contact with the superimposed hard material layer. This malfunction may have the following aspects:

(1) Layered hard materials, like carbides, have material characteristics that are significantly different from those of steel-iron materials (significantly higher elastic moduli, smaller expansion coefficients, etc.). Under load, these layers exhibit only linear-elastic, but not plastic characteristics. Due to the large elastic module, crack-free layer excursions are limited in the elastic region. As a result, an upper load limit is reached at relatively small layer excursions, with the steel matrix still exhibiting elastic properties, while cracks are formed in the hard material layer. This phenomenon which is known from the metal-ceramic layer technology and typical for composite materials, requires treatment of the composite layer-steel in spite of the microscopically small dimensions as a very demanding building block, if a high load-bearing capability and wear resistence are desired.

(2) The hard material layers disposed on the steel are always subjected to a (high) tangential internal stress and are therefore capable of absorbing perpendicular to the surface layer excursions in the vertical direction without forming cracks—while simultaneously reducing the tangential internal stress in the elastic range. An excess load applied vertically on a point on the surface, which creates a plastic deformation in the underlying base material, can be absorbed by the layer without forming cracks, as long as tangential internal stress is still present in the region of maximum excursion. As a result, uneven regions in highly stressed slide planes can be smoothed permanently, wherein the ceramic nature of the hard material layers prevents the overloaded contact locations from becoming welded together, which may otherwise be the case. As a result, the load-bearing capability of specific layers of the system is automatically improved, which may explain the high load-bearing capability of such hard material layers.

(3) Although the layers exhibit advantages layer characteristics under a vertical excess load, the effect of a load introduced tangentially into the layer may be viewed differently. Layer excursions induced in the horizontal direction by large local friction forces are advantageously absorbed along the force direction due to the internal stress of the layer. However, a shear motion is introduced relative to adjacent regions which are less stressed and which therefore also have a smaller displacement, wherein the shear motion can be transmitted by the layer only within linear-elastic limits without creating cracks. The relative excursions, however, are smaller than in the steel matrix due to the high elastic module of the layered materials, so that a local horizontal excess load may form cracks in the layer relatively quickly. In addition, because the base material has a smaller elastic module, it can continue to be elastically deformed, independent of the inherent reserve for additional deformation in the plastic range.

(4) The discussions under (2) and (3) only apply to the situation where the hard material layer is connected with a homogeneous steel matrix. If, however, carbide inclusions are embedded in the marginal zone of the steel matrix, then these attributes become less applicable with increasing size (in relation to the layer thickness) of the carbides or the carbide formation. When the diagonal dimensions of the carbides are approximately twice the layer thickness, then the carbides anchored in the base material resemble non-movable pillars in a flowing stream. The carbides complicate the stress characteristics between the layer, the carbide and the base material, and the defect potential and the tendency to form tears also increases noticeably. In particular with a threshold load, and more particularly with a changing load, the stress in contact with large carbides can cause fractures. The “fixed points” in the carbide are sometimes viewed as desirable anchor points of the layer for enhancing the adhesion properties. However, this applies only to a small carbide size in the range of the layer thickness, i.e., only to the secondary carbides discussed above.

(5) Finish machining, in particular polishing, of the surfaces disadvantageously removes the carbides more slowly because of their larger hardness than the hardened, but nevertheless softer steel matrix, so that after extended polishing a raised, so-called carbide relief is formed. This relief extends the layer surface. Such raised portions (frequently in the order of the layer thickness) are only rarely recognized before coating. Their frequency increases with the size of the carbide or with the carbide concentration. Higher relief structures can significantly weaken the load-bearing fraction. The accumulation of material and the changing shear forces can cause the raised portions to become detached, to break off and to create—as typical secondary damage—grooves extending through the layer. The broken-out damaged areas form attack points for cold welding, which causes striations and scoring of the contacting slide partner.

(6) A similar, but less pronounced relief structure can also be formed if the preceding sputter cleaning, which in PVD processes precedes the actual coating phase to improve the adhesion of the layers, was too intense. This is due to the fact that for carbides the threshold energy for removing material is always greater than for the steel matrix, so that the steel matrix is sputtered off more quickly.

(7) The intensity of the defect concentration inherent in the composite system can be appreciated even more when taking into consideration the aforedescribed defect potential in fragile and partially dislodged primary carbides associated with cutting operations, in particular at angled surface transitions, and more particular with small radii, protruding corners and cutting edges.

It could be concluded from considering these defects, that steels free from primary carbides have a more advantageous load-bearing capacity. Such steels, however, have neither a sufficient hardness nor an adequate temperature resistance. In particular, they do not adequately support the hard material layers under high loads, as required for high-performance tools.

It is therefore an object of the invention to eliminate the aforedescribed defect potentials of the primary carbide and to provide a tool which has a highly reliable layer system which can withstand high loads and is resistant to wear.

### SUMMARY OF THE INVENTION

According to one aspect of the present invention, in a method for surface treatment of tools made of tool steel and having primary carbides embedded in a steel matrix of the tool steel, the primary carbides are uncovered and/or cut and/or protrude in form a relief on the surface. The primary carbides are then either detached by forming a point-wise recessed surface or are entirely removed, and a single-layer or multi-layer hard material layer is deposited on the surface.

According to another aspect of the present invention, a tool made of a tool steel has primary carbides embedded in a steel matrix of the tool steel and a surface manufactured according to the aforedescribed method. The primary carbides are either recessed in a marginal steel region by a predetermined amount between at least 1 μm and approximately twice the layer thickness or are completely removed. A single-layer or multi-layer CVD hard material layer completely fills these recesses or cavities together with components of the removed primary carbides, thereby providing point-wise distributed form-fitting anchors for the layers in the base material. The anchors improve the resistance of the hard material layer against alternating shear stress and also improve adhesion.

According to yet another aspect of the present invention, a tool made of tool steel has primary carbides embedded in a steel matrix of the tool steel and a surface manufactured according to the aforedescribed method. The primary carbides in a marginal steel region are recessed by a predetermined amount between at least about 1 μm and 4 μm and a PVD hard material layer coats or fills the recesses, thereby providing point-wise distributed form-fitting anchors for the layers in the base material to increase the resistance of the PVD hard material layer against alternating shear stress and improve the adhesion. To further increase the load-bearing capability of the compound system, a micro-tooth arrangement between the hard material layer and the base material is also provided, as well as a nitration-hardening of the marginal region of the steel. According to an aspect of the invention, the hard material layer can be deposited by either a CVD or a PVD process.

### BRIEF DESCRIPTION OF THE DRAWINGS

FIG. 1 shows a schematic diagram of an untreated surface of a tool;

FIG. 2 shows a schematic diagram in which a primary carbide is electrically reduced in thickness;

FIG. 3 shows a schematic diagram of a primary carbide reduced in thickness by a CVD process as well as rounding of edges and formation of a bead after carbide reduction with the CVD process;

FIGS. 4 and 5 show a schematic diagram of a hard material layer deposited by PVD, wherein the PVD layer has trough-shaped recesses and a micro-tooth arrangement for engagement with the base material, shown in FIG. 5, wherein the base material is in addition nitration-hardened; FIGS. 6 and 7 show a schematic diagram of a CVD layer on a primary carbide which has been reduced in thickness, wherein the layer has a micro-tooth arrangement for engagement with the base material, as shown in FIG. 7;

FIG. 8 shows a schematic diagram of an untreated cutting edge in the region of a primary carbide having cuts formed on both sides and detached on one side due to formation of a crack;

FIG. 9 shows a schematic diagram of a cutting edge coated by a PVD process;

FIG. 10 shows a schematic diagram of a cutting edge coated by a CVD process and a crack filled by the CVD process, respectively;

FIG. 11 shows a schematic diagram of a carbide relief;

FIG. 12 shows a schematic diagram of a bead smoothed by polishing;

FIG. 13 shows a schematic diagram of an optimally formed PVD layer in the region of a primary carbide; and

FIG. 14 shows a schematic diagram of an optimally formed three-layer CVD layer in the region of a primary carbide.

### DETAILED DESCRIPTION OF PREFERRED EMBODIMENTS

In the CVD coating process, specifically selected gasses are provided in the same thermal-chemical process to chemically and/or thermally reduce the thickness of the primary carbides and/or dislodge the primary carbides to a predetermined depth immediately before the start of the actual coating. Typically, the predetermined depth is in the range between one micrometer to twice the layer thickness.

Alternatively, the primary carbides can be reduced in thickness or dislodged galvanically or chemically with a liquid medium in a separate process prior to the CVD deposition.

In a PVD process, the primary carbides are initially reduced in thickness or dislodged galvanically or chemically in a separate process using a liquid medium to a predetermined depth. This predetermined depth is preferably in the range of one micrometer to twice the layer thickness.

An surface of a tool before treatment is shown in FIG. 1. The primary carbides 3 and the secondary carbides 4 are embedded in the steel matrix tool. A crack 6 caused by machining is located next to the primary carbide, wherein the crack extends to the substrate surface 1. Additional cracks 7, which also extend to the substrate surface, are formed in the primary carbide as a result of machining. The machining direction is indicated by the reference numeral 5. The primary carbide can also protrude from the substrate surface. Such a carbide relief 20 is illustrated in FIG. 11.

According to an aspect of the method of the invention, the work surfaces which define the functionality of the tool, are first machined, i.e., cut, lapped or polished. Before the coating operation, the cut or uncovered primary carbides are removed to a predetermined depth or, alternatively, completely removed from the steel matrix near the marginal region. The carbide can be removed in a separate treatment prior to the coating or—as is possible only with the CVD process—during the coating process itself.

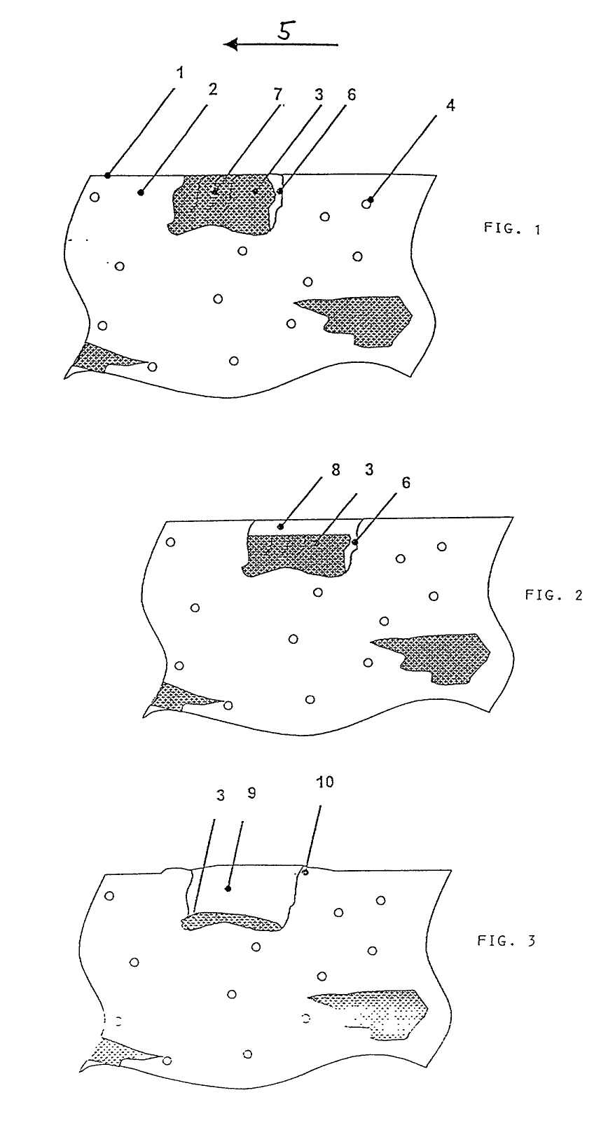

If the carbide is removed—as with the PVD process—prior to coating in a separate treatment with a liquid, for example in an alkaline electrolyte, then the composition of the electrolyte should be selected so that preferably only the primary carbides are dissolved or removed. The removal of the carbide and the intensity with which the carbide is removed, i.e., the speed and the depth of the removal, are controlled by the chemical composition and concentration of the electrolyte and the electrical current, the bath temperature and the immersion time. Shown in FIG. 2 is the region of an electrically reduced primary carbide. If the thickness of the carbide is reduced with a liquid, the treated work piece disadvantageously afterwards has to pass various cleaning and neutralizing baths, followed by intensive drying, which can cause the surfaces to be coated to rust or to become contaminated, adversely affecting the adhesion of the layers.

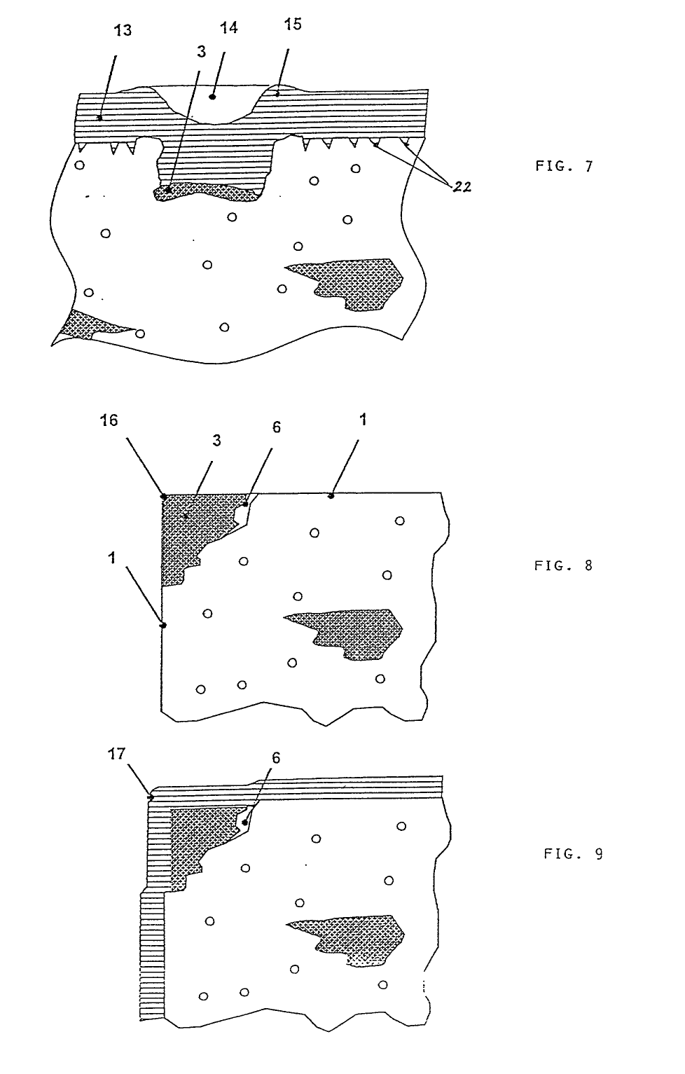

Layers deposited by the PVD process are illustrated in FIGS. 4 and 5. The deposited hard material layer 11 is disposed on the substrate surface and forms trough-shaped recesses 12. Is this a typical feature of the PVD process that the crack 6 is not or only insignificantly filled, i.e., the crack is not “cemented shut” and the adverse impact of the gap is still present and may even be enhanced. Also illustrated in FIG. 5 is a micro-tooth arrangement 22 which enhances the load bearing characteristic, and a nitration zone 23. FIG. 8 shows an uncoated cutting edge 16 with a primary carbide disposed at a disadvantageous position and a crack 6 caused by machining. The cutting edge 17 coated by PVD is illustrated in FIG. 9. The primary carbide is advantageously recessed by partial removal of material. As depicted in FIGS. 4 and 5, the gaps, however, are not filled or “cemented shut”, thereby forming particularly critical defects.

By using CVD coating, however, removal of carbide can be directly integrated in the coating process as an “in situ” starting phase. In this case, substances which dissolve carbide are heated, rapidly flowing, highly reactive and etching process gases. The composition of these gases can be adjusted at will with a gas supply unit, and can thereby be adapted selectively and sequentially to the materials to be treated. Accordingly, the CVD process provides the following advantages:

(a) In contrast to the liquid phase, the gas phase can enter even the smallest cracks and the deepest openings, so that these openings and cracks can be completely decontaminated, de-passivated and rounded, thereby significantly improving the layer adhesion.

(b) According to (1), the detached, splintered or dislodged carbides can be reduced in thickness in the gaseous reactive medium more rapidly due to the significantly increased contact surface area—in particular in these openings and cracks, thereby concentrating the defect reduction mainly in those areas that have the highest concentration of defects.

(c) With the adaptability of the composition of the process gasses used to dislodge the carbides, the walls and edges of the hollowed carbide clusters and crevices, respectively, can be alloyed with alloy components of the dislodged carbides and the steel matrix, whereby even small cracks can be sealed and sharp grooves, corners and edges can be filled and rounded. Advantageous preconditions for the subsequent coating and formation of layers in these recesses, similar to “sealing”, are produced regarding the fracture mechanics.

(d) A transition phase (in situ) can be superimposed with the phase of removing carbides, either simultaneously or with a time offset. In the transition phase, reduction of the carbide and the formation of the layer are carried out simultaneously or with a time offset, which may advantageously support the alloying, sealing or smoothing effect according to (c) and/or coat the steel matrix ahead of time.

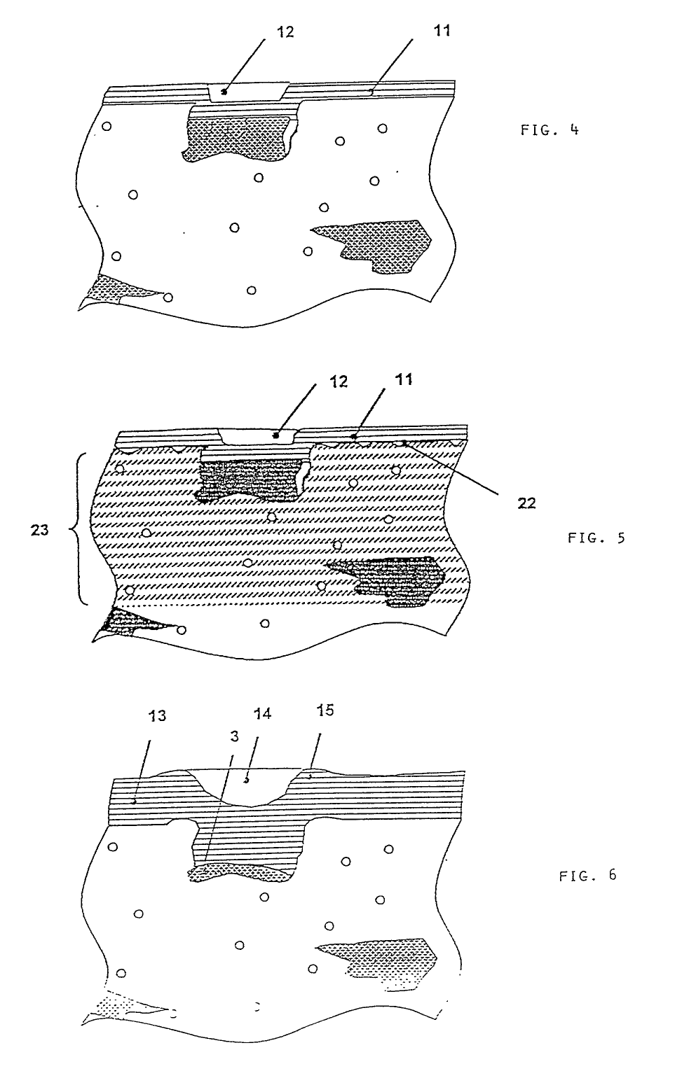

FIG. 3 illustrates the advantages of removing the carbide using the CVD process. The edges 10 are also rounded in the region 9 of the removed primary carbide under formation of a bead.

The removal of carbide produces point-like recesses and/or recesses with a small area in the otherwise unchanged work surface, wherein the recessed depth of the carbides is selected depending on the layer thickness, the coating method, the carbide formation and the load bearing characteristics. The recessed depth should typically not be greater than about 30% to 200% of the layer thickness, wherein recesses of approximately 1 to 2 μm represent the lower limit. These values can already adequately ameliorate the disadvantages of the relief formation according to (5) and (6), and provide the layer with additional support in the recesses.

A CVD layer after the removal of the carbide is shown in FIGS. 6 and 7. The CVD layer 13 is about twice to three times as thick as the PVD layer and forms troughs 14. A bead 15 is transferred to the layer surface. Also illustrated in FIG. 7 is the micro-tooth arrangement 22 between the layer and the base material.

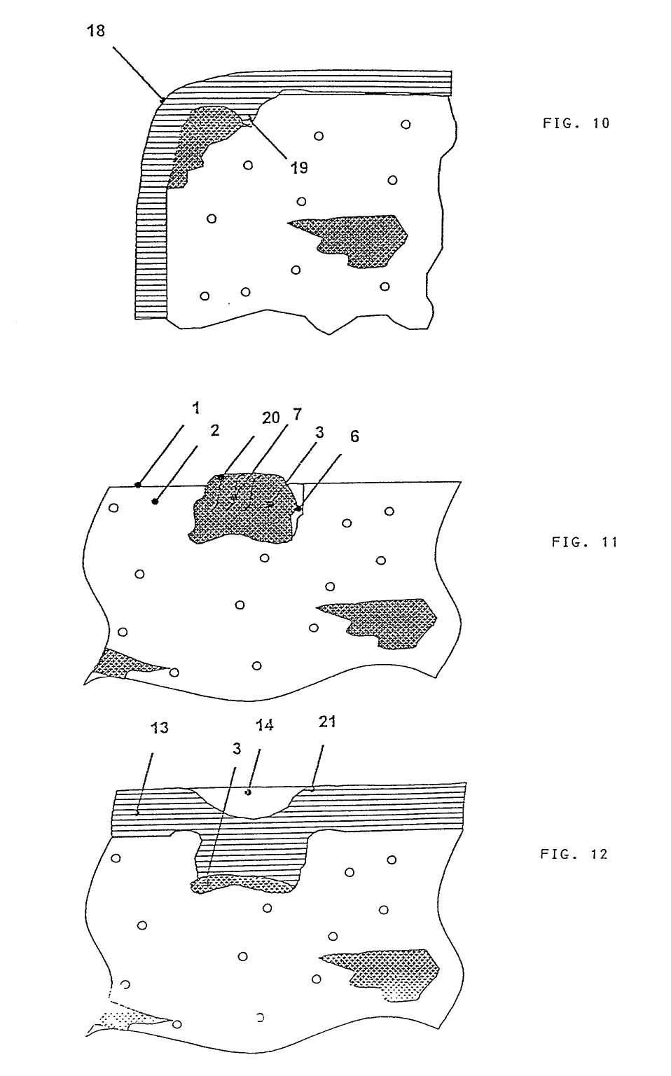

In this way, CVD can be used to coat primary carbides which are unfavorably embedded, without causing them to break off. As seen in FIG. 10, a cutting edge 18 coated with CVD and a primary carbide embedded therein are advantageously rounded. Moreover, a previously existing crack 6 has expanded to from a rounded crack 19 and is completely filled with a CVD layer, thereby not only relieving, but completely “cementing in” the shrunken and recessed primary carbide.

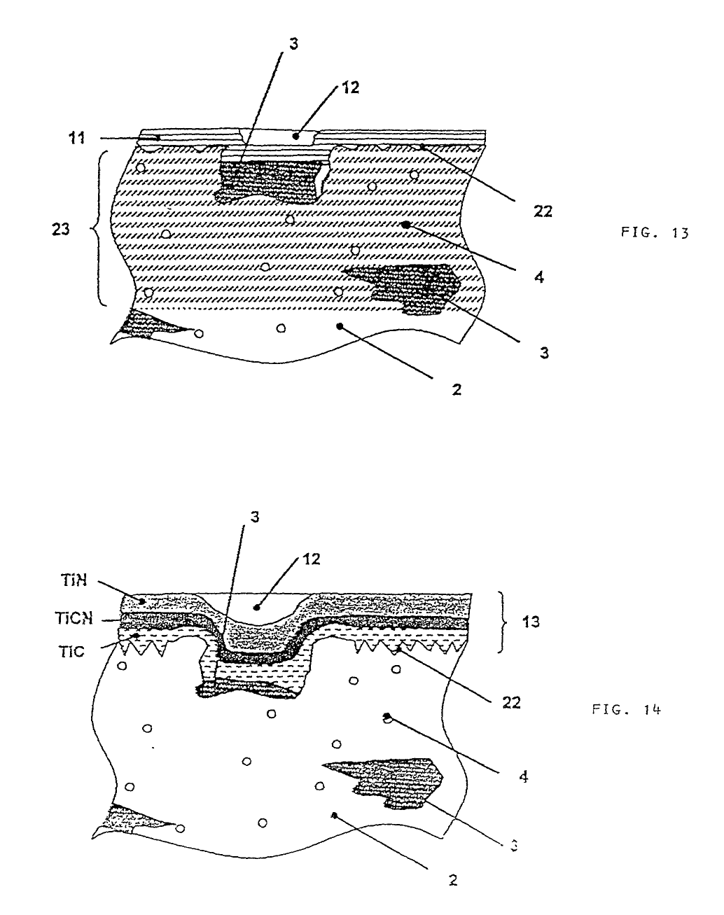

Beads 15 which may appear, as illustrated in FIGS. 6 and 7, can be easily removed by diamond polishing. This is shown in FIG. 12 wherein a previously existing bead 15 has been smoothed and now forms a rounded edge 21.

Depending on the layer thickness, flat recesses in the layer surface may be perceived over the removed carbides. These recesses can advantageously be used as depositories for liquid or solid lubricants. These flat, trough-shaped recesses, as shown for example in FIGS. 4 to 7 and 12, significantly improve the slide friction characteristics, in particular under conditions of minimal quantity lubrication or insufficient lubrication. The depth of the carbide recesses is limited for the (PVD) layers which are only several micrometers thick, so that a complete removal of the primary carbides is not advisable and the defect potential can not be reduced within the theoretical limits. The depth of the lubricant depository can also not be adjusted optimally in this case.

(e) The CVD coating technique can also deposit continuous hard material layers in narrowly angled and deep cracks, thereby always providing completely coated and filled carbide nests, as illustrated in FIGS. 6, 7 and 10. In conjunction with the measures for suppressing the effect of notches described under (c) and (d), CVD therefore provides the best prerequisites for anchoring layers with a minimum tendency for mechanical fracture. A lubricant enclosed in the cavity and compressed periodically can therefore no longer cause a critical wedge action or cavitation, since openings and cracks do no longer exist, and also due to the formation of the hard material layer. The wedge action and cavitation would otherwise preferably attack below the layer, causing the layer to detach. The coating capability typical for CVI (chemical vapor infiltration) of the CVD coating technique provides enhanced protection against premature layer damage in particular in the fanned-out cavities of previously existing carbide accumulations.

(f) With the disposition characteristics typical for CVI of the CVD coating technique, coating material can be deposited in the smallest openings and cracks. According to (a) and (b), the openings and cracks not only sealed before coating, but also cemented shut with the coating material to support external loads. Torn, brittle or dislodged carbides are thereby etched along the formed openings and/or cracks and then firmly secured to and “cemented in” the steel matrix, as indicated in FIG. 10 with the reference number 19. This further reduces the effect of notches and wedges, thereby significantly reducing the aforedescribed defect potentials caused by the primary carbides.

(g) According to another aspect of the CVD coating technique, a thermal and/or chemical and/or thermal-chemical intermediate treatment can precede the actual layer disposition in the same process (in situ). The surface of the base material can be conditioned in a number of ways, for example, by deliberately micro-roughening the steel matrix in an additional process phase, which may be done after removing the carbide and before applying the coating. As illustrated in FIG. 7, micro-roughening facilitates the formation of a very fine micro-tooth arrangement 22 between the steel matrix and the layer at the beginning of the layer growth. Micro-roughening in conjunction with the layer support in the region of the recessed primary carbides also increases the adhesion and resistance to alternating shear stress.

The particular characteristics of the CVD process described under (a) to (f) allow a strategic treatment of the base material and of other applied layers to reduce defects. For example, the composition and the manufacture of the steel and the carbide formation associated therewith (cast, forged or rolled) on the type of load (cutting, stamping, sheet metal forming or bulk forming tools) and on the tool material can be individually addressed. For example, based on the “sealing effect” according to (c), only a small amount of carbide would be removed if a sharp cutting edge is required. For an extreme load on an edge with a greater radius, however, more carbide would be removed, accompanied by a corresponding coating of the formed cracks, carbide nests or cavities. When “adhering” sheets are formed, for example sheets made of aluminum, a smaller recessed depth of the carbide may be preferred. The trough-shaped recesses can be filled with molybdenum sulfide (MoS₂), with hexagonal boron nitride (hBN) or with a similar friction-reducing solid lubricant, which can be implemented as a final phase in the same CVD process.

With the tool of the invention which is coated by CVD, the primary carbides can be recessed in the marginal steel region in a predetermined amount by at least 1 μm to approximately twice the layer thickness or can be completely removed. The single-layer or multi-layer CVD hard material layer together with components of the removed primary carbides completely fills these recesses or cavities, thereby providing point-wise distributed, form-fitting anchors for the layers in the base material to enhance the resistance of the hard material layer against alternating shear stress and improve the adhesion.

The primary carbides in the marginal steel region of the tool according to the invention made of tool steel and having a PVD layer system with a reduced number of defects, are recessed in a predetermined amount by at least 1 μm to 4 μm. The PVD hard material layer coats these recesses, thereby providing point-wise distributed form-fitting support for the layers in the base material. This arrangement enhances the resistance of the PVD hard material layer against alternating shear stress and improve the adhesion. This effect can be enhanced by nitration-hardening before PVD coating of the marginal steel region.

The PVD layer also includes a form-fitting micro-tooth arrangement between the layer and the steel matrix. In addition, the PVD layer has point-shaped or trough-shaped recesses disposed about the recessed carbides according to DIN4761-A1B, which form lubrication pockets.

The invention will be described with reference to the following examples.

### EXAMPLES

### Example 1

Carbide removal for a PVD coating.

For PVD coating, carbide can only be removed by a separate process. An electrolytic bath is used for removing primary carbides, for example carbides of the type M₇C₃,, wherein the electrolyte consist of an alkaline solution, such as 5% soda lye.

To increase the mechanical load-bearing capacity, the tool surface can be micro-roughened before or after removal of the carbide, but always before the PVD coating up to approximately ½ of the layer thickness by fine-grain blasting with Al₂O₃ or SiC. In addition, the marginal steel region can also be nitration-hardened to a depth of about 100 times the layer thickness using a plasma, before the PVD coating is applied.

An optimally formed tool surface with a PVD layer is schematically illustrated in FIG. 13.

### Example 2

Carbide removal for a CVD coating.

With CVD coatings, carbide is removed in situ, i.e., in the same coating operation, in a temperature range of 800-1,000° C. in an argon-hydrogen-HCl mixture. Time, temperature and gas composition determine the removal intensity and the removal depth, respectively, and the alloying, rounding, sealing and smoothing of the produced carbide nests. Advantageously, the gas mixture is introduced under reduced pressure and with a correspondingly high gas velocity. Depending on the chlorine fraction, alloying and rounding or smoothing of the carbide nests can be more or less profound. As a result of the alloying of the walls of the carbide nest with the removed primary carbide components, recesses, rounded and coated areas, respectively, are formed in the marginal regions which, however, may extend to the substrate surface forming a slight bead.

At the same time carbide is removed, a suitable donor medium, such as titanium tetra chloride, may already be added to alloy the coating of the carbide nests with titanium. In this way, the carbide nests are coated faster and a layer growth out of these recesses more quickly. Simultaneously, a first hard material layer containing titanium is formed on the steel matrix surfaces. If a different gas mixture, which does not specifically react with carbide but does react with the steel matrix, is introduced into the reactor subsequent to the removal of carbide, then the steel matrix can be slightly etched at certain points, with an etching depth of approximately 3 to 5 μm.

If the actual coating process is started immediately thereafter, then the CVD layer is disposed conformal with the conditioned substrate surface, thereby forming initially a substantially identical layer surface having the same layer topography, which is displaced by the layer thickness. In this way, a very fine micro-tooth arrangement between the layer and the base material can also be formed. At a later time, i.e. with increasing layer thickness and using different gas compositions and different donor materials, the layer topography can be smoothed by applying a multi-layer technique, whereby depending on the roughness requirement, the depth of the micro lubrication pockets can be adjusted to a greater or lesser depth.

Any beads around the micro lubrication pockets, which are determined by the size of the primary carbides and the depth of the removed primary carbide material, are removed by diamond polishing to adjust the roughness to a predetermined roughness. An optimally formed tool surface, for example having a three-layer TiC—TiN—TiCN—CVD layer, is schematically illustrated in FIG. 14.

While the invention has been disclosed in connection with the preferred embodiments shown and described in detail, various modifications and improvements thereon will become readily apparent to those skilled in the art. Accordingly, the spirit and scope of the present invention is to be limited only by the following claims.

What is claimed is:

1. A method for treating a surface of tools made of a tool steel and having primary carbides embedded in a steel matrix of the tool steel, comprising:
exposing the primary carbides embedded in a steel matrix by at least one of uncovering and cutting,
forming a recess in the surface for one of detaching or removing the exposed primary carbides, and
depositing a hard material coating on the surface, the hard material coating comprising at least one layer.

2. The method according to claim 1, wherein alloy components of the detached or removed primary carbides are at least partially used for alloying a bottom of the recess, a wall of the recess or an edge of the recess so as to fill and seal cracks and round and smooth the recesses.

3. The method according to claim 1, wherein the hard material coating is deposited at least partially concurrent with the detaching or removing the exposed primary carbides, and reactions which at least one of remove and supply material under participation of components of the primary carbide, fill the recesses, so that a top surface of the coating layer exhibits at most slight recesses above the detached or removed primary carbides.

4. The method according to claim 1, wherein following the disposition of the hard material coating, a low friction slide layer is deposited on the hard material coating.

5. The method according to claim 4, wherein the slide layer comprises MoS₂ or hexagonal BN

6. The method according to claim 1, wherein exposed primary carbides are cleaned in such a way that the hard material coating is deposited in cracks formed proximate to the exposed primary carbides, for sealing the cracks and to reattaching the detached primary carbides in the steel matrix.

7. The method according to claim 1, wherein after the detachment or removal of the primary carbides and before the deposition of the hard material coating, the steel matrix is etched so as to produce a micro-roughness between 2 and 5 μm.

8. The method according to claim 7, wherein producing the micro-roughness causes a formation of a micro-tooth arrangement between the hard material coating and the steel matrix for improving the resistance against alternating shear stress and improving adhesion of the hard material coating to the steel matrix.

9. The method according to claim 7, wherein after the detaching or removal of the primary carbides and the etching, however before the deposition of the hard material coating, the steel matrix is treated thermo-chemically in such a way that growth nuclei are created in grain boundary regions, which growth nuclei facilitate layer growth in the grain boundary regions and thereby provide an additional form-fitting anchoring mechanism between the hard material coating and the steel matrix.

10. The method according to claim 1, wherein the primary carbides are galvanically or chemically removed or dissolved to a predetermined depth of between at least 1 μm and twice the thickness of the hard material coating by a separate process using a liquid medium.

11. The method according to claim 1, wherein the hard material layer is deposited using a CVD process.

12. The method according to claim 11, wherein immediately before the hard material coating is deposited using the CVD process, at least one gas is selected for at least one of removing and dissolving the primary carbides to a predetermined depth of between at least 1 μm and twice the layer thickness in the same CVD process.

13. The method according to claim 1, wherein the hard material coating is deposited using a PVD process.

14. The method according to claim 13, wherein before the hard material coating is deposited with the PVD process, a marginal region of the steel matrix is nitration-hardened with a plasma to a depth of one hundred times the thickness of the hard material coating.

15. A tool made of a tool steel comprising:
primary carbide particles embedded in the tool steel, and
a hard material coating having at least one layer and deposited by a CVD process on a surface of the tool steel,
wherein the primary carbides are recessed from the surface of the tool steel by a predetermined amount between at least 1 μm and approximately twice the thickness of the hard material coating, thereby providing distributed form-fitting anchors between the hard material coating and the surface of the tool steel, which anchors improve the resistance of the hard material layer against alternating shear stress and also improve adhesion.

16. The tool according to claim 15, wherein above the recessed primary carbides, the CVD hard material coating forms coating recesses substantially conformal with the recessed primary carbides and having a depth of between at least 1 μm and approximately twice the thickness of the hard material coating, the coating recesses operating as lubrication pockets.

17. The tool according to claim 15, wherein the CVD hard material coating comprises a micro-tooth arrangement disposed between the CVD hard material coating and the surface of the tool steel, thereby increasing adhesion between the hard material coating hard material coating and the tool steel.

18. The tool according to claim 16, wherein the CVD hard material coating extends at least partially in the tool steel to a depth of half the thickness of the hard material coating, thereby providing an additional anchoring mechanism between the hard material coating and the tool steel.

19. A tool made of a tool steel comprising:
primary carbide particles embedded in the tool steel, and
a hard material coating having at least one layer and deposited by a PVD process on a surface of the tool steel,
wherein the primary carbides are recessed by a predetermined amount between at least 1 μm and approximately 4 μm, thereby providing distributed form-fitting anchors between the hard material coating and the tool steel, which anchors improve the resistance of the hard material layer against alternating shear stress and also improve adhesion between the hard material coating and the tool steel.

20. The tool according to claim 19, wherein the PVD hard material coating further comprises a micro-tooth arrangement disposed between the hard material coating and the tool steel.

21. The tool according to claim 19, wherein the PVD hard material coating comprises coating recesses located above the recessed primary carbides and operating as lubrication pockets for storing a lubricant.

22. The tool according to claim 19, wherein a marginal region of the tool steel is additionally strengthened by plasma nitration-hardening to a depth of about 100 times the thickness of the hard material coating.

23. The tool according to claim 16, wherein the coating recesses act as a friction-reducing depository for a lubricant.

24. The tool according to claim 23, wherein the lubricant is molybdenum disulfide (MoS₂) or hexagonal boron nitride (hBN).

25. The tool according to claim 21, wherein the lubricant is molybdenum disulfide (MoS₂) or hexagonal boron nitride (hBN).
